(19) United States
(12) Patent Application Publication
(10) Pub. No.: US 2026/0060078 A1
(43) Pub. Date: Feb. 26, 2026

(54) HEAT CONDUCTION SHEET, HEAT DISSIPATING DEVICE, AND METHOD OF MANUFACTURING HEAT CONDUCTION SHEET

(71) Applicant: RESONAC CORPORATION, Tokyo (JP)

(72) Inventors: Mika KOBUNE, Tokyo (JP); Ricardo Mizoguchi GORGOLL, Tokyo (JP)

(21) Appl. No.: 19/376,193

(22) Filed: Oct. 31, 2025

Related U.S. Application Data
(63) Continuation of application No. 18/861,878.

(30) Foreign Application Priority Data
Jul. 22, 2022 (WO) PCT/JP2022/028527

(51) Int. Cl. H01L 23/373

(52) U.S. Cl. CPC H01L 23/373

(57) ABSTRACT

A heat conduction sheet includes a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and the heat conduction sheet contains a metal component having a melting point of 200° C. or less.

### CROSS-REFERENCE TO RELATED APPLICATIONS

The present application is a continuation application of U.S. Ser. No. 18/861,878, filed on Oct. 31, 2024, which is a National Stage entry of PCT/JP2023/026892, filed on Jul. 21, 2023, which claims priority to PCT/JP2022/028527, filed on Jul. 22, 2022. The entire disclosure of each of the above applications is incorporated herein by reference.

### TECHNICAL FIELD

The present invention relates to a heat conduction sheet, a heat dissipating device, and a method of manufacturing the heat conduction sheet.

In recent years, the amount of heat generation increases due to high density of mounting density of the wiring and the electronic component in the semiconductor package using a multilayered wiring board, and the amount of heat generation per unit area increases due to the high integration of semiconductor devices. There is a growing demand for increased heat dissipation from semiconductor packages.

In general, a heat dissipating device for dissipating heat by closely adhering a heat conduction grease or a heat conduction sheet between a heat generating body such as a semiconductor package and a heat dissipating body such as aluminum or copper is simply used. In general, heat conduction sheets are superior to heat conduction greases in workability when assembling the heat dissipating device.

In recent years, chips of CPU (central processing unit) tend to be larger in area by multi-core and multi-chip. Further, there is a tendency to lower the pressure of pressure bonding between CPU that is a heat generating body and a heat dissipating body. Therefore, the heat conduction sheet is required to have flexibility at the time of pressure bonding. Further, the heat conduction sheet is required to be excellent in the thermal conductivity so that even if the heat conduction sheet becomes thick due to the chip level difference, the heat conduction sheet has a low thermal resistance.

As the heat conduction sheet, it is also known a resin sheet filled with heat conduction filler. As a resin sheet excellent in the thermal conductivity filled with the heat conduction filler, various resin sheets have been proposed in which inorganic particles with a high thermal conductivity are selected as the heat conduction filler, and further the inorganic particles are oriented perpendicularly to the sheet surface.

For example, the heat conduction sheet (see, for example, Patent Literature 1) in which a heat conduction filler (boron nitride) is oriented in a direction substantially perpendicular to the sheet surface, and the heat conduction sheet (see, for example, Patent Literature 2) having the structure that carbon fibers dispersed in a gel-like substance is oriented perpendicular to the sheet surface has been proposed.

### CITATION LIST

### Patent Literature

Patent Literature 1: Japanese Patent Application Laid-Open (JP-A) No. 2002-26202
Patent Literature 2: Japanese Patent Application Laid-Open (JP-A) No. 2001-250894

### SUMMARY OF INVENTION

### Technical Problem

In Patent Documents 1 and 2, a method of suppressing thermal resistance by orienting a heat conduction filler, a carbon fiber, or the like in a direction perpendicular to the sheet surface is considered. In order to cope with the increase in heat generation due to the high performance and large size of semiconductors, it is desired to further reduce the thermal resistance of heat conduction sheets. Therefore, it is preferable to reduce the thermal resistance by taking into account methods other than the orientation of a heat conduction filler, a carbon fiber, or the like contained in the heat conduction sheet.

It is an object of the present invention to provide a heat conduction sheet with a low thermal resistance, a heat dissipating device provided with this heat conduction sheet and a method of manufacturing a heat conduction sheet capable of manufacturing a heat conduction sheet with a low thermal resistance.

### Solution to Problem

Specific means for addressing the above problem include the following aspects.

<1> A heat conduction sheet, comprising:
a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet,
wherein the heat conduction sheet contains a metal component having a melting point of 200° C. or less.
   <2> The heat conduction sheet according to <1>, wherein the metal component is particulate.
   <3> The heat conduction sheet according to <1> or <2>, wherein the metal component is located on at least a part of a main surface of the heat conduction layer.
   <4> The heat conduction sheet according to any one of <1> to <3>, wherein the melting point of the metal component is 60° C. or more.
   <5> The heat conduction sheet according to any one of <1> to <4>, wherein the metal component contains at least one element selected from the group consisting of tin, bismuth, indium, zinc, lead, gallium, cadmium, thallium, and antimony.
   <6> The heat conduction sheet according to any one of <1> to <5>, wherein graphite particles (A): carbon fibers, which is a mass ratio of the graphite particles (A) and the carbon fibers in the heat conduction layer is from 100:0 to 100:30.
   <7> A heat conduction sheet, comprising:
a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet,
wherein when the heat conduction sheet is heat-compression bonded between a heat generating body and a heat dissipating body, in at least one of an interface between the heat generating body and the heat conduction sheet or an interface between the heat dissipating body and the heat conduction sheet, a void ratio calculated as a ratio of an area of a gas region with respect to an area of a measurement region is from 0% to 8%.
   <8> A heat dissipating device, comprising a heat generating body, a heat dissipating body, and the heat conduction sheet according to any one of <1> to <6> interposed between the heat generating body and the heat dissipating body,
wherein in the heat conduction layer, a metal region containing the metal component is located on at least a part of a main surface located on the heat generating body side or a main surface located on the heat dissipating body side.
   <9> A heat dissipating device, comprising a heat generating body, a heat dissipating body, and the heat conduction sheet according to any one of claims <1> to <7> interposed between the heat generating body and the heat dissipating body,
wherein in at least one of an interface between the heat generating body and the heat conduction sheet or an interface between the heat dissipating body and the heat conduction sheet, a void ratio calculated as a ratio of an area of a gas region with respect to an area of a measurement region is from 0% to 8%.
   <10> A method of manufacturing the heat conduction sheet according to any one of <1> to <6>, comprising:
a step of preparing a composition containing the graphite particles (A), and a step of producing a heat conduction sheet containing the metal component using the composition.
   <11> The method of manufacturing the heat conduction sheet according to <10>, wherein the step of producing the heat conduction sheet includes a step of forming the heat conduction layer and a step of attaching the metal component on at least a part of a surface of the heat conduction layer.
   <12> The method of manufacturing the heat conduction sheet according to <10> or <11>, wherein the composition, which is prepared in the step of preparing the composition, contains the graphite particles and the metal component.

### Advantageous Effects of Invention

In the present disclosure, a heat conduction sheet with a low thermal resistance, a heat dissipating device provided with this heat conduction sheet and a method of manufacturing a heat conduction sheet capable of manufacturing a heat conduction sheet with a low thermal resistance can be provided.

### BRIEF DESCRIPTION OF DRAWINGS

FIG. 1 is a schematic configuration view of a heat conduction sheet in which a particulate low melting point metal component is located on main surfaces of a heat conduction layer, which is an embodiment of the present invention.

FIG. 2 is a schematic cross-sectional view of a heat conduction sheet in which a particulate low melting point metal component is located inside a heat conduction layer, which is an embodiment of the present invention.

FIG. 3 is a schematic cross-sectional view of a heat conduction sheet in which metal regions containing low melting point metal component are located on main surfaces of a heat conduction layer, which is an embodiment of the present invention.

FIG. 4 is a schematic cross-sectional view of a heat dissipating device, which is an embodiment of the present invention, when a heat generating body is a semiconductor chip and a heat dissipating body is a heat spreader.

FIG. 5 is a view showing the state of the interface by image analysis in Examples 1 to 4 and Comparative Example 1.

### DESCRIPTION OF EMBODIMENTS

Hereinafter, modes for carrying out the present invention will be described in detail. However, the present invention is not limited to the following embodiments. In the following embodiments, the constituent elements (including element steps and the like) are not essential unless otherwise specified. The same applies to numerical values and ranges thereof, and does not limit the present invention.

In the present disclosure, the term “step” includes, in addition to steps independent of other steps, such steps as long as the purpose of the step is achieved even if it cannot be clearly distinguished from other steps.

In the present disclosure, those numerical ranges that are expressed with “to” each denote a range that includes the numerical values stated before and after “to” as the minimum value and the maximum value, respectively.

In a set of numerical ranges that are stated stepwise in the present disclosure, the upper limit value or the lower limit value of a numerical range may be replaced with the upper limit value or the lower limit value of other numerical range. Further, in a numerical range stated in the present disclosure, the upper limit value or the lower limit value of the numerical range may be replaced with a value indicated in Examples.

In the present disclosure, each component may contain plural kinds of substances that correspond to the indicated component. In a case in which there are plural kinds of substances that correspond to the component in a composition, the indicated content ratio or content of the component in the composition means, unless otherwise specified, the total content ratio or content of the plural kinds of substances existing in the composition.

In the present disclosure, each component may contain plural kinds of particles that correspond to the indicated component. In a case in which there are plural kinds of particles that correspond to the component in a composition, the indicated particle size of the component in the composition means, unless otherwise specified, a value determined for a mixture of the plural kinds of particles existing in the composition.

In the present disclosure, the term “layer” or “film” includes, in addition to the case where the region is entirely formed, that when the region where the layer or the film is present is observed, it is formed in only a part of the region.

In the present disclosure, the term “layered” refers to stacking layers, two or more layers may be combined, and two or more layers may be removable.

### [Heat Conduction Layer]

A heat conduction sheet of the present disclosure includes a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and the heat conduction sheet contains a metal component (also referred to as “low melting point metal component”) having a melting point of 200° C. or less.

The heat conduction sheet of the present disclosure includes a heat conduction layer in which the graphite particles (A) is oriented in the thickness direction, and thereby it is considered that thermal conductivity in the thickness direction is excellent and a low thermal resistance is shown.

Furthermore, the heat conduction sheet is considered to exhibit lower thermal resistance by containing the low melting point metal component. The reason for this is assumed to be as follows. Note that the present disclosure is not limited to the following speculations. In the heat conduction sheet in which the graphite particles (A) are oriented in the thickness direction, there are unevennesses on a surface that contacts an adherend, and most of the heat resistance is derived from the resistance (also referred to as “contact thermal resistance”) due to a gap generated by contact of the heat conduction sheet and the adherend such as a heat generating body, a heat dissipating body or the like, which is contact with the heat conduction sheet. In the heat conduction sheet of the present disclosure, by using a low melting point metal component, which is a metal component having a relatively low melting point, the low melting point metal component is melted when the heat conduction sheet and the adherend such as a heat generating body, a heat dissipating body or the like are heat-compression bonded. Furthermore, the application of pressure makes it easier for the molten low melting point metal component to be localized at the interface between the heat conduction sheet and the adherend, and the heat conduction sheet and the adherend can be brought into close contact via the molten low melting point metal component. At this time, a gap (for example, a gap resulting from unevenness of the heat conduction sheet) that is generated when the heat conduction sheet and the adherend are heat-compression bonded, is filled with the molten low melting point metal component, thereby significantly reducing contact thermal resistance.

Contact thermal resistance is also likely to occur when there are unevennesses on a surface of an adherend such as a heat generating body or a heat dissipating body. In this case, it is difficult to reduce the thermal resistance by adjusting the orientation of the heat conduction filler contained in the heat conduction sheet. On the other hand, by using the heat conduction sheet of the present disclosure, the heat conduction sheet and the adherend having unevennesses on a surface can be brought into close contact via the low melting point metal component melted by heating. At this time, the molten low melting point metal component fills a gap generated when the heat conduction sheet and the adherend are heat-compression bonded (for example, a gap resulting from unevenness of the adherend), thereby significantly reducing contact thermal resistance.

The heat conduction sheet of the present disclosure contains at least graphite particles (A) and a low melting point metal component and may contain a component described below to the extent that the effect of the present disclosure are achieved. Hereinafter, materials used in the heat conduction layer of the present disclosure will be described.

### <Graphite Particles (A)>

The heat conduction layer included in the heat conduction sheet includes graphite particles (A). The graphite particles (A) are considered to function mainly as a high thermal conductivity filler. The graphite particles (A) are at least one kind selected from the group consisting of scale-like particles, ellipsoidal particles and rod-like particles. In a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet. It is preferable that a six-membered ring plane is oriented in a plane direction of the particle in a case of scale-like particles, is oriented in a long axis direction of the particle in a case of ellipsoidal particles, and is oriented in a long axis direction in a case of rod-like particles. A six-membered ring plane is a plane in which a six-membered ring is formed in a hexagonal system, and means a (0001) crystal plane.

It is more preferable that a shape of the graphite particles (A) is scale-like. By selecting a scale-like graphite particles, the thermal conductivity tends to be further improved. This reason can be considered, for example, for the scale-like graphite particles to be more easily oriented in a predetermined direction in the heat conduction layer.

Whether the six-membered ring plane in the crystal is oriented in the plane direction of scale-like particles, the long axis direction of ellipsoidal particles or the long axis direction of rod-like particles, it can be confirmed by X-ray diffraction measurement. The orientation direction of the six-membered ring plane in the crystal of the graphite particle (A) is specifically confirmed by the following method.

At first, a sample sheet for measurement in which the plane direction of scale-like particles, the long axis direction of ellipsoidal particles or the long axis direction of rod-like particles in the graphite particles (A) is oriented along the sheet direction is prepared. As a specific preparation method of the measurement sample sheet, for example, the following method may be mentioned.

A mixture of a resin and the graphite particles (A) in an amount of 10% by volume or more with respect to the resin is sheeted. The “resin” used herein is not particularly limited as long as a material that does not exhibit a peak that interferes with X-ray diffraction and that can form a sheet. Specifically, an amorphous resin having a cohesive force as a binder can be used, such as acrylic rubber, NBR (acrylonitrile butadiene rubber), SIBS (styrene-isobutylene-styrene copolymer), or the like.

The sheet of this mixture is pressed so as to be 1/10 or less of the original thickness, and a plurality of pressed sheets are layered to form a layered body. The operation of further crushing this layered body to the thickness of 1/10 or less is repeated three times or more to obtain a sample sheet for measurement. By this operation, in a case of scale-like particles, a plane direction of the particle is oriented in a plane direction of the sample sheet, in a case of ellipsoidal particles, a long axis direction of the particle is oriented in the plane direction of the sample sheet, and in a case of rod-like particles, a long axis direction of the particle is oriented in the plane direction of the sample sheet.

The X-ray diffraction measurement is performed to the surface of the measurement sample sheet prepared as described above. The height H₁ of the peak corresponding to the (110) plane of graphite appearing around 2θ=77° and the height H₂ of the peak corresponding to the (002) plane of graphite appearing around 20=27° are measured. In the measurement sample sheet prepared in this manner, the value obtained by dividing H₁ by H₂ is 0 to 0.02.

From this, it can be seen that “the six-membered ring plane in the crystal of the graphite particle (A) is oriented in the plane direction of scale-like particles, the long axis direction of ellipsoidal particles or the long axis direction of rod-like particles” means that X-ray diffraction measurement is performed on the surface of the sheet including the graphite particle (A), and the value obtained by dividing the peak height corresponding to the (110) plane of the graphite particle (A) appearing around 2θ=77° by the peak height corresponding to the (002) plane of the graphite particle (A) appearing near 2θ=27° is 0 to 0.02.

In the present disclosure, X-ray diffraction measurement is performed under the following conditions.
Device: Bruker AXS KK “D8DISCOVER”
X-ray source: CuKα wavelength 1.5406 nm, 40 kV, 40 mA
Step (measurement step size): 0.01° Step time: 720 sec

Herein, “in a case of scale-like particles, a plane direction of the particle is oriented in a thickness direction of the heat conduction layer, and in a case of ellipsoidal particles or rod-like particles, a long axis direction of the particle is oriented in the thickness direction of the heat conduction layer” means that the angle (hereinafter also referred to as “orientation angle”) between a plane direction in a case of scale-like particles, a long axis direction in a case of ellipsoidal particles or a long axis direction in a case of rod-like particles, and the surface (main surface) of the heat conduction layer is 60° or more. The orientation angle is preferably 80° or more, more preferably 85° or more, and still more preferably 88° or more.

The orientation angle is an average value when a cross section of the heat conduction layer is observed with SEM (scanning electron microscope), and the angle (orientation angle) between a plane direction in a case of scale-like particles, a long axis direction in a case of ellipsoidal particles or a long axis direction in a case of rod-like particles, and the surface (main surface) of the heat conduction layer for arbitrary 50 graphite particles (A) is measured.

The particle size of the graphite particles (A) is not particularly limited. The average particle size of the graphite particles (A) is preferably a half of the average thickness to the average thickness of the heat conduction layer. When the average particle size of the graphite particles (A) is a half or more of the average thickness of the heat conduction layer, an efficient heat conduction path tends to be formed in the heat conduction layer, and the thermal conductivity tends to be improved. When the average particle size of the graphite particles (A) is equal to or less than the average thickness of the heat conduction layer, the protrusion of the graphite particles (A) from the surface of the heat conduction layer is suppressed, and the adhesion of the surface of the heat conduction layer tends to be excellent.

A method of manufacturing a heat conduction layer so as to be oriented in the plane direction of scale-like particles, the long axis direction of ellipsoidal particles or the long axis direction of rod-like particles, is not particularly limited and for example, the method described in JP-A No. 2008-280496 can be used. Specifically, a method can be used in which sheets are prepared using a composition, the sheets are layered to prepare a layered body, and the side end face of the layered body is sliced (for example, at an angle of 0° to 30° with respect to the normal line extending from the main surface of the layered body) (hereinafter, also referred to as the “layered slice method”).

In the case of using the above-mentioned layered slice method, the particle size of the graphite particles (A) used as the raw material, as a mass average particle size, is preferably a half times or more of the average thickness of the heat conduction layer, and may exceed the average thickness. The reason why the particle size of the graphite particles (A) used as the raw material may exceed the average thickness of the heat conduction layer is, for example, even if the graphite particles (A) having a particle size exceeding the average thickness of the heat conduction layer are included, because the graphite particles (A) are sliced to form the heat conduction layer, the graphite particles (A) do not project from the surface of the heat conduction layer as a result. Further, when the whole graphite particles (A) are sliced in this manner, a large number of graphite particles (A) penetrating in the thickness direction of the heat conduction layer are generated, extremely efficient heat conduction paths are formed, and the heat conductivity tends to be further improved.

When using the layered slice method, the particle size of the graphite particles (A) used as the raw material, as a mass average particle size is more preferably from 1 to 5 times of the average thickness of the heat conduction layer. When the mass average particle size of the graphite particles (A) is 1 or more times the average thickness of the heat conduction layer, a more efficient heat conduction path is formed, and the thermal conductivity is further improved. When the average thickness of the heat conduction layer is 5 times or less, the area of the graphite particles (A) to the surface can be prevented from being too large, and the decrease in the adhesion can be suppressed.

The mass average particle size of the graphite particles (A) (D50) is measured by using a laser diffraction type particle size distribution device adapted to laser diffraction scattering method (e.g., manufactured by Nikkiso Co., Ltd. “Microtrac Series MT3300”), and when the weight cumulative particle size distribution curve is drawn from the small particle size side, it corresponds to the particle size at which the weight cumulative becomes 50%.

The heat conduction layer may contain particles other than scale-like particles, ellipsoidal particles or rod-like particles as graphite particles, and may contain spherical graphite particles, artificial graphite particles, exfoliated graphite particles, acid-treated graphite particles, expanded graphite particles, carbon fibers or the like.

As the graphite particles (A), scale-like particles are preferable, and, from the viewpoint of easily obtaining a scaly having a high degree of crystallinity and a large particle size, scale-like expanded graphite particles obtained by pulverizing sheeted expanded graphite are preferable.

The content ratio of the graphite particles (A) in the heat conduction layer is, for example, from the viewpoint of the balance between the thermal conductivity and the adhesion is preferably from 15% by volume to 50% by volume, more preferably from 20% by volume to 45% by volume, and still more preferably from 25% by volume to 40% by volume.

When the content ratio of the graphite particles (A) is 15% by volume or more, the thermal conductivity tends to be further improved. When the content ratio of the graphite particles (A) is 50% by volume or less, the decrease in the adhesiveness and the adhesion tends to be suppressed.

When the heat conduction layer contains graphite particles other than scale-like particles, ellipsoidal particles or rod-like particles, the content ratio of the entire graphite particles is preferably included in the above range.

The content ratio of the graphite particles (A) (% by volume) is determined by the following Formula.

$$Content ratio ( \% by volume ) of graphite particles ( A ) = \{ ( Aw / Ad ) / ( ( Aw / Ad ) + ( Xw / Xd ) ) \} \times 100$$

Aw: mass composition (% by mass) of graphite particles (A)
Xw: mass composition (% by mass) of other optional ingredients
Ad: density of graphite particles (A) (in the present specification, Ad is calculated with 2.1)
Xd: density of other optional ingredients

The content ratio of the spherical graphite particles, artificial graphite particles, acid-treated graphite particles, or carbon fibers in the heat conduction layer may be each independently from 0% by volume to 10% by volume, may be from 0% by volume to 5% by volume, or may be from 0% by volume to 1% by volume.

Graphite particles (A): carbon fibers, which is a mass ratio of the graphite particles (A) and the carbon fibers in the heat conduction layer may be from 100:0 to 100:30, may be from 100:0 to 100:20, or may be from 100:0 to 100:10. Since carbon fibers are generally hard, by using a smaller amount of carbon fibers than graphite particles (A), the flexibility of the heat conduction sheet can be ensured and an increase in contact thermal resistance tends to be suppressed.

### <Metal Component>

The heat conduction sheet of the present disclosure contains a metal component (low melting point metal component) having a melting point of 200° C. or less.

In the heat conduction sheet of the present disclosure, the low melting point metal component may be particulate. In this case, the heat conduction sheet of the present disclosure may be a member prior to heat-compression bonding with an adherend such as a heat generating body or a heat dissipating body. In the heat conduction sheet heat-compression bonded to an adherend such as a heat generating body or a heat dissipating body, the particulate low melting point metal component has been in a molten state, so the low melting point metal component does not have to be particulate.

When the low melting point metal component is particulate, the particle size of the low melting point metal component is not particularly limited and may be from 0.5 μm to 60 μm, may be from 1 μm to 30 μm, or may be from 5 μm to 15 μm.

The particle size (D50) of the low melting point metal component is measured using a laser diffraction particle size distribution device (for example, “Microtrack series MT3300” manufactured by Nikkiso Co., Ltd.) adapted to a laser diffraction/scattering method, and when a mass cumulative particle size distribution curve is drawn from the small particle size side, D50 corresponds to the particle size at which the mass accumulation is 50%.

In the heat conduction sheet of the present disclosure, the arrangement of the low melting point metal component is not particularly limited, and may be disposed on a surface of the heat conduction layer, or may be contained inside the heat conduction layer, for example. In the heat conduction sheet of the present disclosure, the low melting point metal component is preferably located on at least a part of a main surface of the heat conduction layer, from the viewpoint of suitably reducing the contact thermal resistance by suitably filling a gap generated when the heat conduction sheet and the adherend are heat-compression bonded together with the molten low melting point metal component.

When the low melting point metal component is located on at least a part of a main surface of the heat conduction layer, the low melting point metal component may be disposed on the entire main surface, or may be disposed on a part of the main surface (for example, a part in contact with an adherend such as a heat generating body or a heat dissipating body).

When a low melting point metal component is located on at least a part of a main surface of the heat conduction layer, the low melting point metal component may be disposed on one main surface, or may be disposed on two main surfaces.

The melting point of the low melting point metal component is not particularly limited as long as it is 200° C. or less, and is preferably 60° C. or more from the viewpoint of suppressing melting of the low melting point metal component when the heat conduction sheet is used for heat dissipation purposes, and is preferably from 80° C. to 180° C., and more preferably 80° C. to 160° C., from the viewpoint of more suitably reducing the contact thermal resistance.

The composition of the low melting point metal component is not limited as long as it contains a metal element. The metal element also include a non-metal element that can exhibit similar properties to a metal element. The low melting point metal component preferably contains at least one element selected from the group consisting of, for example, tin, bismuth, indium, zinc, lead, gallium, cadmium, thallium, and antimony.

The low melting point metal component is preferably a low melting point solder having a melting point of 200° C. or less, and more preferably a low melting point lead-free solder having a melting point of 200° C. or less. Specific examples of the low melting point solder include Sn—Bi solder, Sn—In solder, Bi—In solder, Sn—Zn solder, Bi—Sn—In solder, and Sn—Zn—Bi solder.

The content ratio of the low melting point metal component contained in the heat conduction sheet is preferably from 0.1% by volume to 20% by volume, more preferably from 0.5% by volume to 15% by volume, and still more preferably from 1% by volume to 10% by volume, with respect to the total amount of the heat conduction sheet, from the viewpoint of the balance between thermal conductivity and adhesion.

In the present disclosure, the content ratio of the low melting point metal component contained in the heat conduction sheet means the total content ratio of the low melting point metal component disposed on the surface of the heat conduction layer and the low melting point metal component contained inside the heat conduction layer.

<Component (B) that is Liquid at 25° C.>

The heat conduction layer contained in the heat conduction sheet of the present disclosure may contain a component (B) that is liquid at 25° C. (hereinafter, also referred to as “liquid component (B)”). In the present disclosure, “liquid at 25° C.” means a substance that shows fluidity and viscidity at 25° C. and has a viscosity as a measure of viscidity is from 0.0001 Pa·s to 1000 Pa·s at 25° C. In the present disclosure, “viscosity” is defined as a value measured at a shear rate of 5.0 s⁻¹ using a rheometer at 25° C. In particular, the “viscosity” is measured as shear viscosity at a temperature of 25° C. using a rotational shear viscometer equipped with a cone plate (diameter 40 mm, cone angle) 0°.

The viscosity of the liquid component (B) at 25° C. is preferably from 0.001 Pa·s to 100 Pa·s, or more preferably from 0.01 Pa·s to 10 Pa·s.

The liquid component (B) is not particularly limited as long as it is liquid at 25° C., and is preferably a high molecular compound (polymer). Examples of the liquid component (B) include polybutene, polyisoprene, polysulfide, acrylonitrile rubber, silicone rubber, hydrocarbon resin, terpene resin, and acrylic resin. Among these, from the viewpoint of heat resistance, the liquid component (B) preferably contains polybutene. The liquid component (B) may be used alone or in combination of two or more.

Herein, polybutene refers to a polymer obtained by polymerizing isobutene or normal butene. It also includes polymers obtained by copolymerizing isobutene and normal butene. It refers to a polymer having a structural unit represented by “—CH₂—C(CH₃)₂—” or “—CH₂—CH(CH₂CH₃)—” as the structure. It is also sometimes called polyisobutylene. The polybutene only needs to contain the above structure, and other structures are not particularly limited.

Examples of the polybutene include a butene homopolymer and a copolymer of butene and another monomer component. Examples of the copolymer with another monomer component include a copolymer of isobutene and styrene or a copolymer of isobutene and ethylene. The copolymer may be a random copolymer, a block copolymer, or a graft copolymer.

Examples of the polybutene include NOF Corporation's “NOF Polybutene™ Emawet (registered trademark)” JXTG Nippon Oil & Energy Corporation's “Nippon Oil Polybutene” JXTG Nippon Oil & Energy Corporation's “Tetrax” JXTG Nippon Oil & Energy Corporation's “Himol” and Tomoe Engineering Co., Ltd.'s “Polyisobutylene”.

It is thought that the liquid component (B) mainly functions as, for example, a stress reliever and a tackifier, which have excellent heat resistance and humidity resistance. Further, by using it in combination with a hot melt agent (D) described below, there is a tendency that cohesive force, and fluidity during heating can be more improved.

The content ratio of the liquid component (B) in the heat conduction layer is preferably from 10% by volume to 55% by volume, more preferably from 15% by volume to 50% by volume, and still more preferably from 20% volume to 50% by volume from the viewpoint of further increasing adhesive strength, adhesion, sheet strength, hydrolysis resistance, or the like.

When the content ratio of the liquid component (B) is 10% by volume or more, adhesiveness and adhesion tend to be improved. When the content ratio of the liquid component (B) is 55% by volume, there is a tendency that decreases in sheet strength and thermal conductivity can be effectively suppressed.

### <Acrylic Acid Ester Polymer (C)>

The heat conduction layer included in the heat conduction sheet may contain an acrylic ester polymer (C). It is thought that the acrylic ester polymer (C) mainly functions as, for example, a tackifier and an elasticity-imparting agent that allows the thickness to be restored in order to follow warpage.

As the acrylic acid ester-based polymer (C), for example, an acrylic acid ester-based polymer (so-called acrylic rubber) obtained by copolymerizing butyl acrylate, ethyl acrylate, acrylonitrile, acrylic acid, glycidyl methacrylate, 2-ethylhexyl acrylate, or the like as a main raw material component and, if necessary, methyl acrylate, or the like, is preferably used. The acrylic ester polymer (C) may be used alone or in combination of two or more.

The weight average molecular weight of the acrylic ester polymer (C) is preferably from 100,000 to 1,000,000, more preferably from 250,000 to 700,000, and still more preferably from 400,000 to 600,000. When the weight average molecular weight is 100,000 or more, film strength tends to be excellent, and when it is 1,000,000 or less, flexibility tends to be excellent.

The weight average molecular weight can be measured by gel permeation chromatography using a standard polystyrene calibration curve.

The glass transition temperature (Tg) of the acrylic acid ester polymer (C) is preferably 20° C. or lower, more preferably from −70° C. to 0° C., and still more preferably from −50° C. to −20° C. When the glass transition temperature is 20° C. or lower, flexibility and adhesiveness tend to be excellent.

The glass transition temperature (Tg) can be calculated from the tan 8 derived from dynamic viscoelasticity measurement by tension.

The acrylic ester polymer (C) may be present in the entire heat conduction layer by internal addition, or may be localized on a surface by applying or impregnating it on the surface. In particular, applying it on one side or impregnating it on one side is preferable because strong tackiness can be imparted to only one side, resulting in a sheet with good handling properties.

In the heat conduction layer, the content ratio of the acrylic ester polymer (C) is preferably from 3% by volume to 25% by volume, more preferably from 5% by volume to 20% by volume, and still more preferably from 7% by volume to 15% by volume.

### <Hot Melt Agent (D)>

The heat conduction layer included in the heat conduction sheet may contain a hot melt agent (D). The hot melt agent (D) has the effect of improving the strength of the heat conduction layer and improving the fluidity during heating.

Examples of the hot melt agent (D) include an aromatic petroleum resin, a terpene phenol resin, and a cyclopentadiene petroleum resin. Further, the hot melt agent (D) may be a hydrogenated aromatic petroleum resin or a hydrogenated terpene phenol resin. The hot melt agent (D) may be used alone or in combination of two or more.

Among them, when polybutene is used as the liquid component (B), the hot melt agent (D) preferably contains at least one selected from the group consisting of a hydrogenated aromatic petroleum resin and a hydrogenated terpene phenol resin. These hot melt agents (D) have high stability and excellent compatibility with polybutene, so they tend to be able to achieve better thermal conductivity, flexibility, and handleability when forming a heat conduction layer.

Commercially available hydrogenated aromatic petroleum resins include, for example, “Alcon” by Arakawa Chemical Co., Ltd. and “Imarv” by Idemitsu Kosan Co., Ltd. Furthermore, examples of commercially available hydrogenated terpene phenol resins include “Clearon” manufactured by Yasuhara Chemical Co., Ltd. Commercially available cyclopentadiene petroleum resins include, for example, “Quinton” manufactured by Nippon Zeon Co., Ltd. and “Marcarez” manufactured by Maruzen Petrochemical Co., Ltd.

The hot melt agent (D) is solid at 25° C. and preferably has a softening temperature of from 40° C. to 150° C. When a thermoplastic resin is used as the hot melt agent (D), the softening fluidity during thermocompression bonding is improved, and as a result, adhesion tends to be improved. Further, when the softening temperature is 40° C. or higher, cohesive force can be maintained near room temperature, and as a result, it becomes easier to obtain the necessary sheet strength and tends to be excellent in handleability. When the softening temperature is 150° C. or less, the softening fluidity during thermocompression bonding becomes high, and as a result, adhesion tends to improve. The softening temperature is more preferably from 60° C. to 120° C. Note that the softening temperature is measured by the ring and ball method (JIS K 2207:1996).

The content ratio of the hot melt agent (D) in the heat conduction layer is preferably from 3% by volume to 25% by volume, more preferably from 5% by volume to 20% by volume, and still more preferably from 5% by volume to 15% by volume, from the viewpoint of improving adhesive strength, adhesion, sheet strength, or the like.

When the content ratio of the hot melt agent (D) is 3% by volume or more, adhesive strength, heat fluidity, sheet strength, or the like tend to be sufficient, and when the content ratio is 25% by volume or less, there is a tendency that flexibility is sufficient and handling properties and thermal cycle resistance are excellent.

### <Antioxidant (E)>

The heat conduction layer included in the heat conduction sheet may contain an antioxidant, for example, for the purpose of imparting thermal stability at a high temperature. Examples of the antioxidant (E) include a phenolic type antioxidant, a phosphorus type antioxidant, an amine type antioxidant, a sulfur type antioxidant, a hydrazine type antioxidant, an amide type antioxidant and the like. The antioxidant (E) may be appropriately selected depending on the temperature conditions used, or the like, and a phenolic antioxidant is more preferable. The antioxidant (E) may be used alone or in combination of two or more.

Commercially available phenolic antioxidants include, for example, ADEKA STAB AO-50, ADEKA STAB AO-60, and ADEKA STAB AO-80 manufactured by ADEKA Corporation.

The content ratio of the antioxidant (E) in the heat conduction layer is not particularly limited, and is preferably from 0.1% by volume to 5% by volume, more preferably from 0.2% by volume to 3% by volume, and still more preferably from 0.3% by volume to 1% by volume. When the content ratio of the antioxidant (E) is 0.1% by volume or more, a sufficient antioxidant effect tends to be obtained. When the content ratio of the antioxidant (E) is 5% by volume or less, the strength of the heat conduction layer tends to be prevented from decreasing.

### <Other Ingredients>

The heat conduction layer included in the heat conduction sheet may include other ingredients other than the graphite particles (A), the low melting point metal component, the liquid component (B), the acrylic ester polymer (C), the hot melt agent (D), or the antioxidant (E) depending on the purpose. For example, the heat conduction layer may include a flame retardant for the purpose of imparting flame retardancy. The flame retardant is not particularly limited, and can be appropriately selected from commonly used flame retardants. Examples thereof include a red phosphorus based flame retardant and a phosphoric acid ester based flame retardant can be mentioned. Among them, a phosphoric acid ester based flame retardant is preferable from the viewpoint of excellent safety and improved adhesion due to plasticizing effect.

As the red phosphorus based flame retardants, in addition to pure red phosphorus particles, those provided with various coatings for the purpose of improving safety or stability, or those made into a masterbatch may be used. Specific examples thereof include Nova Red, Nova Excel, Nova Cell, Nova Pellet (all trade names) manufactured by RIN KAGAKU KOGYO Co., Ltd., and the like.

Examples of the phosphoric acid ester based flame retardant include an aliphatic phosphoric acid ester such as trimethyl phosphate, triethyl phosphate, or tributyl phosphate; an aromatic phosphate ester such as triphenyl phosphate, tricresyl phosphate, cresyl diphenyl phosphate, trixylenyl phosphate, cresyl di 2,6-xylenyl phosphate, tris(t-butylated phenyl) phosphate, tris(isopropylated phenyl) phosphate, or triaryl isopropylated phosphate; an aromatic condensed phosphoric acid ester such as resorcinol bisdiphenyl phosphate, bisphenol A bis(diphenyl phosphate), or resorcinol bisdixylenyl phosphate.

Among these, bisphenol A bis(diphenyl phosphate) is preferable from the viewpoint of being excellent in hydrolysis resistance and excellent in the effect of improving the adhesion by a plasticizing effect.

The content ratio of the flame retardant in the heat conduction layer is not limited and may be used in an amount that flame retardancy is exhibited, preferably on the order 30% by volume or less, and from the viewpoint of suppressing the deterioration of the heat resistance due to the flame retardant component exuding to a surface of the heat conduction layer, preferably 20% by volume or less.

The average thickness of the heat conduction sheet is not particularly limited, it can be appropriately selected depending on the purpose. The thickness of the heat conduction sheet can be appropriately selected depending on the specifications of a semiconductor package to be used, or the like. The smaller the thickness, the lower the thermal resistance tends to be, and the larger the thickness, the higher the warp conformability tends to be. The average thickness of the heat conduction sheet may be from 50 μm to 3000 μm, and from the viewpoint of the thermal conductivity and the adhesion, is preferably from 100 μm to 500 μm, and still more preferably from 100 μm to 300 μm. The average thickness of the heat conduction layer is randomly measured at three locations using a micrometer, and is given as an arithmetic average value.

The heat conduction sheet may have a protective film on at least one side, and preferably has a protective film on both sides. This can protect the adhesive side of the heat conduction sheet.

As the protective film, for example, resin films such as polyethylene, polyester, polypropylene, polyethylene terephthalate, polyimide, polyether imide, polyether naphthalate, methyl pentene, and the like, coated paper, coated cloth, and metal foils such as aluminum are used. These protective films may be used alone or in combination of two or more as a multilayer film. The protective film is preferably surface-treated with a silicone-based or silica-based release agent.

The use of the heat conduction sheet is not particularly limited. When the semiconductor chip is the heat generating body and the heat spreader is the heat dissipating body, the heat conduction sheet of the present disclosure is particularly suitable as a heat conduction sheet (TIM1; Thermal Interface Material 1) that interposes a semiconductor chip and a heat spreader.

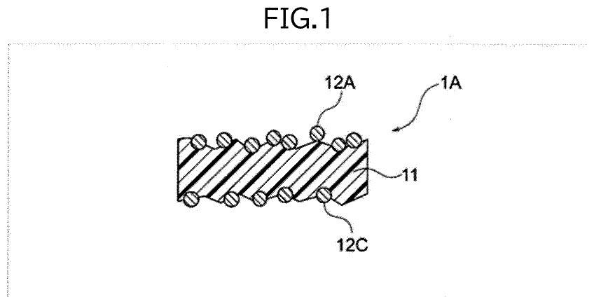

An embodiment of the heat conduction sheet will be described using FIG. 1 to FIG. 3. The heat conduction sheet of the present disclosure is not limited to the following embodiments.

In the heat conduction sheet 1A shown in FIG. 1, a particulate low melting point metal component 12A is located on one main surface of the heat conduction layer 11 and a particulate low melting point metal component 12C is located on other main surface of the heat conduction layer 11.

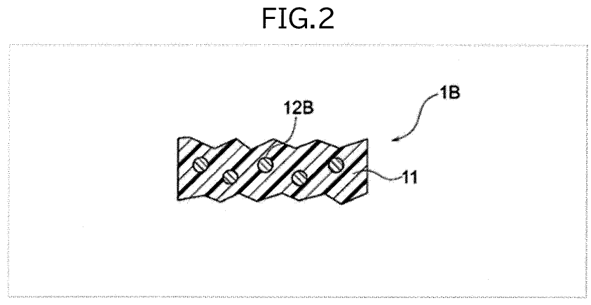

In the heat conduction sheet 1B shown in FIG. 2, a particulate low melting point metal component 12B is located inside the heat conduction layer 11.

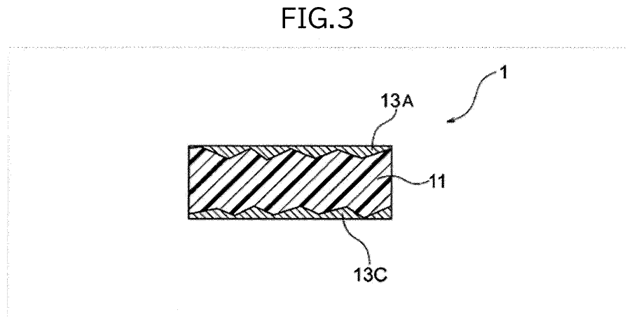

In the heat conduction sheet 1 shown in FIG. 3, a metal region 13A containing a low melting point metal component is located on one main surface of the heat conduction layer 11 and a metal region 13C containing a low melting point metal component is located on the other main surface of the heat conduction layer 11.

### (Modified Example of Heat Conduction Sheet)

A modified example of the heat conduction sheet of the present disclosure includes a heat conduction layer containing at least one kind of graphite particles (A) selected from the group consisting of scale-like particles, ellipsoidal particles and rod-like particles, in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and when the heat conduction sheet is heat-compression bonded between a heat generating body and a heat dissipating body, in at least one of an interface between the heat generating body and the heat conduction sheet or an interface between the heat dissipating body and the heat conduction sheet, a void ratio calculated as a ratio of an area of a gas region with respect to an area of a measurement region is from 0% to 8%.

When the heat conduction sheet is heat-compression bonded between a heat generating body and a heat dissipating body, for example, when forming a heat dissipating device, the aforementioned void ratio is from 0% to 8%. Thus, a gap (for example, a gap resulting from unevenness of the heat conduction sheet or a gap resulting from unevenness of a heat generating body or a heat dissipating device) that is generated when the heat conduction sheet and the heat generating body or the heat dissipating body are heat-compression bonded, is filled with the molten low melting point metal component, thereby significantly reducing contact thermal resistance.

The aforementioned void ratio is preferably from 0% to 6%, and more preferably from 0% to 4% from the viewpoint of further reducing contact thermal resistance.

In the present disclosure, the void ratio at the interface can be determined as follows. First, using an ultrasonic image diagnostic device (for example, Insight-300, manufactured by Insight Co., Ltd.), the adhesion state at the interface is observed under the condition of a reflection method and 35 MHz. The ratio of the area of the non-adhered gas region may be calculated, and the void ratio (%) at the interface may be calculated based on the following formula.

Void ratio (%) at interface=100×(area of gas region/area of measurement region)

The modified example of the heat conduction sheet of the present disclosure may be appropriately combined with the heat conduction sheet of the present disclosure and its preferred embodiments described above. For example, the heat conduction sheet according to the modified example may further contain a metal component having a melting point of 200° C. or less.

### [Method of Manufacturing Heat Conduction Sheet]

A method of manufacturing a heat conduction sheet is not particularly limited as long as it can obtain a heat conduction sheet having the above configuration. Examples of the method of manufacturing a heat conduction sheet include the following method.

In one embodiment, the method of manufacturing a heat conduction sheet includes a step (also referred to as a “preparation step”) of preparing a composition containing graphite particles (A) and any other optional components, and a step (also referred to as a “production step”) of producing a heat conduction sheet containing a low melting point metal component using the composition.

The method of incorporating the low melting point metal component into the heat conduction sheet is not particularly limited, and examples include method 1, in which the low melting point metal component is mixed with the graphite particles (A) or the like when preparing the composition, and method 2, in which the low melting point metal component is attached to at least a part of a surface of the heat conduction layer after the heat conduction layer is formed.

As the method 1, for example, the composition prepared in the preparation step described above may contain graphite particles (A), a low melting point metal component, and any other optional components. The composition may be prepared by mixing the graphite particles (A), the low melting point metal component, and any other optional components. In the method 1, the step of producing a heat conduction sheet may include a step (also referred to as a “forming step”) of forming the heat conduction layer.

As the method 2, for example, the step of producing a heat conduction sheet may include a step (also referred to as a “forming step”) of forming the heat conduction layer, and a step (also referred to as an “attaching step”) of attaching a low melting point metal component on at least a part of a surface of the heat conduction layer.

It is preferable that the formation step in the methods 1 and 2 preferably has a step (also referred to as “sheet forming step”) of forming the composition into a sheet, a step (also referred to as “layered body producing step”) of producing a layered body of the sheets, and a step (also referred to as “slicing step”) of slicing a side end face of the layered body.

In the method 1, a heat conduction sheet containing a low melting point metal component is obtained through the aforementioned slicing step. If necessary, after obtaining the heat conduction sheet containing a low melting point metal component, the low melting point metal component may be attached on at least a part of a surface of the heat conduction layer (i.e., methods 1 and 2 may be used in combination).

In the method 2, it is preferable to carry out a step (also referred to as “attaching step”) of attaching a low melting point metal component on at least a part of a surface of the heat conduction layer obtained in the slicing step. Through the attached step, a heat conduction sheet containing a low melting point metal component can be manufactured.

The method of manufacturing a heat conduction sheet may further include a step (also referred to as “laminating step”) of attaching and laminating the sliced sheet (or the heat conduction sheet containing a low melting point metal component when including the attaching step) obtained in the slicing step to a protective film.

By manufacturing a heat conduction sheet by such a method, an efficient heat conduction path is easily formed, and therefore a heat conduction sheet with excellent high thermal conductivity and adhesion tends to be obtained.

### <Preparation Step>

In the preparation step, a composition containing graphite particles (A) and optional other components (for example, low melting point metal component, component (B) that is liquid at 25° C., acrylic acid ester polymer (C), hot melt agent (D), antioxidant (E), or other ingredients) is prepared. The method of blending each component is not particularly limited, and any method may be used as long as each component can be mixed uniformly. Alternatively, the composition may be prepared by obtaining a commercially available composition. For details on the preparation of the composition, reference can be made to paragraph of JP-A No. 2008-280496.

### <Sheet Forming Step>

The sheet forming step may be performed by any method as long as the composition obtained in the previous step can be formed into a sheet, and is not particularly limited. For example, it is preferable to carry out using at least one forming method selected from the group consisting of rolling, pressing, extrusion, and coating. For details of the sheet forming step, reference can be made to paragraph of JP-A No. 2008-280496.

### <Layered Body Producing Step>

The layered body producing step is a step to forming a layered body of sheets obtained in the previous step. The layered body may be a form in which a plurality of independent sheets are sequentially stacked, may be a form in which one sheet is folded or may be a form in which one sheet is rolled. For details of the layered body producing step, reference can be made to paragraphs to of JP-A No. 2008-280496.

### <Slicing Step>

The slicing step, when the side end face of the layered body obtained in the previous step can be sliced, may be any method, and is not particularly limited. From the viewpoint that a very efficient heat conduction path is formed by the graphite particles (A) penetrating in the thickness direction of the heat conduction sheet and the thermal conductivity is further improved, it is preferable to slice by the thickness of 2 times or less of the mass average particle size of the graphite particles (A). For details of the slicing step, reference can be made to paragraph of JP-A No. 2008-280496.

### <Attaching Step>

The attaching step is not particularly limited and may be any method as long as the low melting point metal component can be attached on at least a part of a surface of the heat conduction layer. For example, metal particles having a melting point of 200° C. or less may be sprinkled on at least a part of a surface of the heat conduction layer, or a low melting point metal component may be attached by a technique such as coating, vapor deposition, or sputtering.

### <Lamination Step>

The lamination step is not particularly limited and may be any method as long as sliced sheet obtained in the slicing step (heat conduction sheet containing low melting point metal component when attaching step is included) can be attached to the protective film.

### [Heat Dissipating Device]

A heat dissipating device of the present disclosure is a device including a heat generating body, a heat dissipating body, and the heat conduction sheet of the present disclosure interposed between the heat generating body and the heat dissipating body, and in the heat conduction layer, a metal region containing the metal component is located on at least a part of a main surface located on the heat generating body side or a main surface located on the heat dissipating body side. It is preferable that a metal region is located on each of at least a part of a main surface located on the heat generating body side and at least a part of a main surface located on the heat dissipating body side, and it is more preferable that a metal region is located on each of on a region facing the heat generating body in a main surface located on the heat generating body side and a region facing the heat dissipating body in a main surface located on the heat dissipating body side.

The metal region containing the low melting point metal component may be in the form of a layer, or may be scattered on the main surface of the heat conduction sheet. The aforementioned metal region may be located on at least a part of a main surface of the heat conduction sheet, and may be contained inside the heat conduction sheet.

Examples of the heat generating body include a semiconductor chip, a semiconductor package, a power module, and the like. Examples of the heat dissipating body include a heat spreader, a heat sink, a water cooling pipe, and the like.

The maximum thickness of the metal region may be from 3 μm to 20 μm or may be from 5 μm to 15 μm on one side from the viewpoint of reducing contact thermal resistance and thermal conductivity. When the maximum thickness is 20 μm or less, it tends to be possible to suppress an increase in bulk thermal resistance corresponding to the thermal conductivity of the metal itself. When the maximum thickness is 3 μm or more, it tends to be possible to obtain a sufficient effect of filling a gap generated when the heat conduction sheet and the adherend are heat-compression bonded, thereby more suitably reducing contact thermal resistance.

The maximum thickness of the heat conduction layer and the maximum thickness of the metal region may be measured by observing a cross section of the measurement target using an electron microscope. Alternatively, the maximum thickness of the heat conduction layer may be measured using a micrometer, or the maximum thickness of the heat conduction layer and the maximum thickness of the heat conduction sheet having the metal region may be measured, and the maximum thickness of the metal region may be measured by subtracting the maximum thickness of the heat conduction layer from the maximum thickness of the heat conduction sheet.

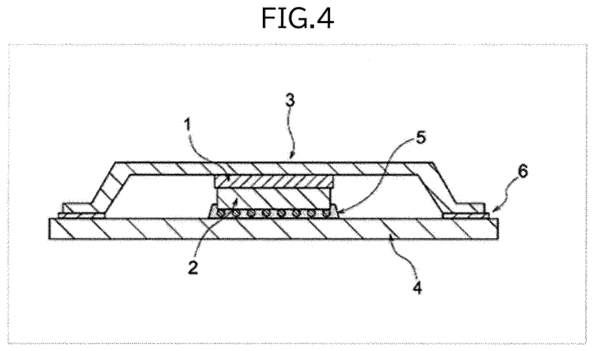

Hereinafter, an example of the heat dissipating device will be described in more detail using FIG. 4. A heat dissipating device using a semiconductor chip as a heat generating body and a heat spreader as a heat dissipating body will be described. A semiconductor chip and a heat spreader are examples of a heat generating body and a heat dissipating body, respectively, and the present disclosure is not limited thereto. The heat conduction sheet 1 is used with one side in close contact with the semiconductor chip 2 and the other side in close contact with the heat spreader 3 (heat dissipating body). The semiconductor chip 2 is fixed to the substrate 4 using an underfill material 5, and the heat spreader 3 is fixed to the substrate 4 by a sealing material 6, and the adhesion between the heat conduction sheet 1, the semiconductor chip 2, and the heat spreader 3 is improved by pressing. Note that it is not necessary that one heat conduction sheet 1 has one heat generating body and one heat dissipating body. For example, a plurality of semiconductor chips 2 may be provided for one heat conduction sheet 1, one semiconductor chip 2 may be provided for a plurality of heat conduction sheets 1, and a plurality of semiconductor chips 2 may be provided for a plurality of heat conduction sheets 1. Each of metal regions containing a low melting point metal component is located on a main surface of the heat conduction sheet 1 on the semiconductor chip 2 side and on the other main surface of the heat conduction sheet 1 on the heat spreader 3 side. For example, in the heat conduction sheet 1 shown in FIG. 3, the metal resin 13A may be located on a main surface of the heat conduction sheet 1 on the semiconductor chip 2 side, and the metal resin 13B may be located on the other main surface of the heat conduction sheet 1 on the heat spreader 3 side. Furthermore, the metal region 13A may be in contact with the heat spreader 3 and the metal region 13C may be in contact with semiconductor chip 2.

The heat dissipating device includes the heat conduction sheet of the present disclosure disposed between a heat generating body and a heat dissipating body. Since the heat generating body and the heat dissipating body are layered via the heat conduction sheet, heat from the heat generating body can be efficiently conducted to the heat dissipating body. Efficient heat conduction is possible, thereby the lifespan of the heat dissipating device is improved, and the heat dissipating device that functions stably even during long-term use can be provided.

The temperature range which can particularly suitably use the heat conduction sheet may be, for example, −40° C. to 150° C., may be −10° C. to 100° C., or may be −10° C. to 80° C. For this reason, suitable examples of the heat generating body include semiconductor packages, displays, LEDs, electric lights, automotive power modules, and industrial power modules.

Examples of the heat dissipating body include a heat sink using aluminum or copper fins or plates, an aluminum or copper block connected to a heat pipe, an aluminum or copper block in which a cooling liquid is circulated by a pump, and a Peltier element and an aluminum or copper block equipped with the same.

The heat dissipating device is constructed by bringing each surface of the heat conduction sheet into contact with the heat generating body and the heat dissipating body. The method of bringing the heat generating body into contact with one side of the heat conduction sheet and the method of bringing the heat dissipating body into contact with the other side of the heat conduction sheet is not particularly limited as long as they can be fixed in a sufficiently close state.

For example, the method that the heat conduction sheet is disposed between the heat generating body and the heat dissipating body, and fixed with a jig that can pressurize to about 0.05 MPa to 1 MPa, and the heat generating body is heated in this state, or they are heated to about 80° C. to 200° C. (for example, temperature equal to or more than melting point of low melting point metal component) in an oven or the like, can be mentioned. Another method that a press machine capable of heating and pressing at 80° C. to 200° C. and 0.05 MPa to 1 MPa, can be mentioned. The preferred pressure range for this method is 0.10 MPa to 1 MPa, and the preferred temperature range is 100° C. to 180° C. Excellent adhesion tends to be obtained by setting the pressure to 0.10 MPa or higher or the heating temperature to 100° C. or higher. Furthermore, when the pressure is 1 MPa or less or the heating temperature is 180° C. or less, the reliability of adhesion tends to be further improved. These reason is considered to be that it is possible to prevent the heat conduction sheet from being excessively compressed and becoming thinner, and from causing excessive distortion or residual stress in a surrounding member.

The heat conduction sheet interposed between the heat generating body and the heat dissipating body is not particularly limited as long as it is the above-mentioned heat conduction sheet. For example, the heat conduction sheet shown in FIG. 1 to FIG. 3 may be disposed between the heat generating body and the heat dissipating body.

When using the heat conduction sheet 1A shown in FIG. 1, by heating and pressurizing the heat conduction sheet 1A disposed between the heat generating body and the heat dissipating body, the low melting point metal component 12A and 12C located on the main surfaces of the heat conduction sheet 1A are molten. A gap generated when the heat conduction sheet 1A and the heat generating body and the heat dissipating body are heat-compression bonded, is filled with the molten low melting point metal component (corresponding to metal regions). As described above, a gap between the heat conduction sheet and the heat generating body or the heat dissipating body is reduced, and the contact thermal resistance is significantly reduced.

When using the heat conduction sheet 1B shown in FIG. 2, by heating and pressurizing the heat conduction sheet 1B disposed between the heat generating body and the heat dissipating body, the low melting point metal component 12B located inside the heat conduction sheet 1A are molten and likely to exuded to the surfaces of the heat conduction sheet 12B. Thereby, a gap generated when the heat conduction sheet 1B and the heat generating body and the heat dissipating body are heat-compression bonded, is filled with the molten low melting point metal component (corresponding to metal regions). As described above, a gap between the heat conduction sheet and the heat generating body or the heat dissipating body is reduced, and the contact thermal resistance is significantly reduced.

As described above, by manufacturing a heat dissipating device using each of the heat conduction sheets 1A and 1B shown in FIGS. 1 and 2, the particulate low melting point metal component melts in a gap between the heat conduction sheet and the heat generating body or the heat dissipating body. As a result, the gap is filled with a metal region derived from the low melting point metal component, making it possible to significantly reduce the contact thermal resistance. When a heat dissipating device is manufactured using each of the heat conduction sheets 1A and 1B shown in FIGS. 1 and 2, the heat conduction sheet included in the heat dissipating device has metal regions derived from the low melting point metal component on two main surfaces of the heat conduction layer as shown in FIG. 3, and the metal regions located on the two main surfaces are in surface contact with the heat generating body and the heat dissipating body, respectively.

When using the heat conduction sheet 1 shown in FIG. 3, by heating and pressurizing the heat conduction sheet 1 disposed between the heat generating body and the heat dissipating body, the metal regions 13A and 13C are molten. A gap generated when the heat conduction sheet 1 and the heat generating body and the heat dissipating body are heat-compression bonded, is filled with the molten metal regions 13A and 13C. As described above, a gap between the heat conduction sheet and the heat generating body or the heat dissipating body is reduced, and the contact thermal resistance is significantly reduced.

The heat conduction sheet may have a ratio (compression ratio) of the reduced thickness after compression with respect to its initial thickness before being disposed between the heat generating body and the heat dissipating body and being compressed, of from 1% to 35%.

In addition to a clip, a jig such as a screw or a spring may be used for fixing, and it is preferable to further fix with commonly used means such as an adhesive in order to maintain close contact.

### (Modified Example of Heat Dissipating Device)

The modified example of the heat dissipating device of the present disclosure includes a heat generating body, a heat dissipating body, and the aforementioned heat conduction sheet of the modified example interposed between the heat generating body and the heat dissipating body, and in at least one of an interface between the heat generating body and the heat conduction sheet or an interface between the heat dissipating body and the heat conduction sheet, a void ratio calculated as a ratio of an area of a gas region with respect to an area of a measurement region is from 0% to 8%.

In the heat dissipating device in which the heat conduction sheet is disposed between a heat generating body and a heat dissipating body, the aforementioned void ratio is from 0% to 8%. Thus, a gap (for example, a gap resulting from unevenness of the heat conduction sheet) that is generated when the heat conduction sheet and the heat generating body or the heat dissipating body are heat-compression bonded, is filled with the molten low melting point metal component, thereby significantly reducing contact thermal resistance.

The modified example of the heat dissipating device of the present disclosure may be appropriately combined with the heat dissipating device of the present disclosure and its preferred embodiment described above. For example, in the heat dissipating device according to the modified example, a metal region containing a low melting point metal component on the heat conduction layer may be located on at least a part of at least one of a main surface located on the heat generating body side and a main surface located on the heat dissipating body side.

### EXAMPLES

Hereinafter, the present invention will be described in more detail with reference to Examples, but the present invention is not limited to these Examples.

### Example 1 to Example 2

The following materials were put into a kneader (Moriyama Co., Ltd., DS3-SGHM-E type pressurized double-arm kneader) so that the mixing ratio (volume %) was as shown in Table 1, and kneaded at a temperature of 150° C., a composition was obtained.

### <Graphite Particles (A)>

(A)-1: Scale-like expanded graphite particles (manufactured by Showa Denko Materials co., Ltd. “HGF-L”, mass average particle size: 270 μm, by a method using X-ray diffraction measurement described above, it was confirmed that the six-membered ring face in the crystal is oriented in the plane direction of the scale-like particles.)

### <Liquid Component (B)>

(B)-1: Isobutene/Normal Butene Copolymer (NOF Corporation “NOF Polybutene Copolymer™ · Emawet (registered trademark), grade 30N”)
(B)-2: Isobutene homopolymer (Nippon Oil Co., Ltd. “Tetrax 6T”)

### <Acrylic Acid Ester Polymer (C)>

(C)-1: Acrylic ester copolymer resin (butyl acrylate/ethyl acrylate/acrylonitrile/acrylic acid copolymer, weight average molecular weight: 530,000, Tg=−39° C.)

### <Hot Melt Agent (D)>

(D)-1: Hydrogenated petroleum resin (Arakawa Chemical Co., Ltd. “Alcon P90”)

### <Antioxidant (E)>

(E)-1: Hindered phenolic antioxidant (ADEKA Co., Ltd. “ADEKA STAB AO-60”)

### (Preparation of Heat Conduction Layer)

A composition obtained by kneading was put into an extrusion molding machine (Parker Co., Ltd., product name: HKS40-15 type extruder) and extruded into a flat plate shape with a width of 20 cm and a thickness of 1.5 mm to 1.6 mm to obtain a primary sheet. The obtained primary sheet was press punched using a 40 mm×150 mm die blade, and 61 of the punched sheets were layered and a spacer with a height of 80 mm was sandwiched so that the height of the sheet was 80 mm, and the pressure was applied for 30 minutes at 90° C. in the layering direction to obtain a layered body with 40 mm×150 mm×80 mm. Next, the side end face with 80 mm×150 mm of this layered body was sliced with a wood slicer to obtain a heat conduction layer with a thickness of 0.11 mm.

### (Preparation of Heat Conduction Sheet)

The two main surfaces of the heat conduction layer obtained as described above were sprinkled with solder particles (component Sn—Bi (tin-bismuth alloy), Tin bismuth alloy powder (manufactured by 5N Plus Inc.), MCP137 (melting point 137° C.), average particle size: 10 μm). Thus, a heat conduction sheet with solder particles attached to the two main surfaces of the heat conduction layer was obtained. The maximum thickness of the region of the solder particles attached to the heat conduction sheet is shown in Table 1.

### Examples 3 and Example 4

Instead of the process of sprinkling solder particles on dusting the two main surfaces of the heat conduction in Examples 1 and 2, the same steps as in Examples 1 and 2 were used for kneading, laminating, pressing, and slicing to prepare a heat conduction layer except that solder particles (component Sn—Bi (tin-bismuth alloy), melting point 137° C.) were added to the composition during the kneading process for producing the heat conduction layer, and the composition was prepared to have the mixing ratio (volume %) shown in Table 1. In each of Examples 3 and 4, the heat conduction layer containing solder particles was used as the heat conduction sheet.

### Comparative Example 1

The same steps as in Examples 1 to 4 were used for kneading, laminating, pressing, and slicing with the materials shown in Table 1 satisfied the mixing ratio (volume %) shown in Table 1 to prepare a heat conduction layer. In Comparative Example 1, the heat conduction layer was used as a heat conduction sheet without using solder particles.

TABLE 1

| | | Example | Example | Example | Example | Comparative |
|---|---|---|---|---|---|---|
| | | 1 | 2 | 3 | 4 | Example 1 |
| Use of low melting | | Attached to | | Added to | | Not used |
| point metal component | | surface | | composition | | |
| Graphite | (A)-1 | 33.8 | 33.8 | 32.8 | 28.8 | 32.8 |
| particles (A) | | | | | | |
| Liquid | (B)-1 | 28.4 | 28.4 | 28.4 | 28.4 | 28.4 |
| component (B) | (B)-2 | 13.1 | 13.1 | 13.1 | 13.1 | 13.1 |
| Acrylic acid | (C)-1 | 10.0 | 10.0 | 10.0 | 10.0 | 10.0 |
| ester polymer (C) | | | | | | |
| Hot melt | (D)-1 | 14.3 | 14.3 | 14.3 | 14.3 | 14.3 |
| agent (D) | | | | | | |
| Antioxidant (E) | (E)-1 | 0.4 | 0.4 | 0.4 | 0.4 | 0.4 |
| Low melting | Sn—Bi | 0 | 0 | 1.0 | 5.0 | 0 |
| point metal | | | | | | |
| component | | | | | | |

| | | | | | |
|---|---|---|---|---|---|
| Total volume % | 100 | 100 | 100 | 100 | 100 |
| Maximum thickness of attached | 8 | 14 | — | — | — |
| low melting point metal | | | | | |
| component (μm) | | | | | |

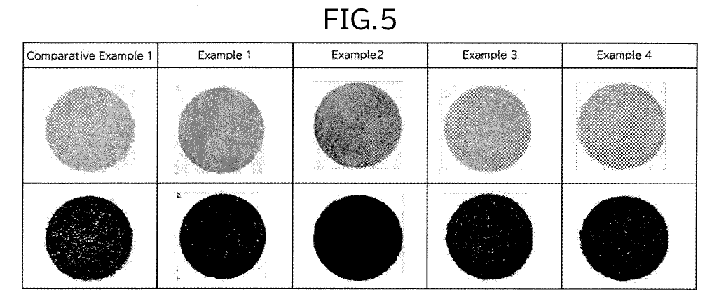

For the heat conduction sheets of Examples 1 to 4 and Comparative Example 1, each evaluation was performed by the following method. The results are shown in Table 2 and FIG. 5.

### (Measurement of Thermal Resistance)

Thermal resistance was measured using a tabletop xenon flash analyzer (LFA 467 Hyper Flash). A sample with a three-layer structure was prepared by sandwiching a punched heat conduction sheet of each of Examples 1 to 4 and Comparative Example 1 with a diameter of 14 mm between 1 mm copper plates. The sample was prepared under the following conditions: temperature 150° C., pressure 120 psi for 3 minutes, and then sufficiently cooled to room temperature. In addition, as a pretreatment for measurement, the copper surface was blackened using carbon spray, and then measured. From the three-layer structure, the thermal conductivity λ excluding the influence of the copper plates is obtained, and from the obtained thermal conductivity λ and the thickness t, the unit area (1 cm²) per thermal resistance value X (K·cm²/W) was calculated as follows.

$$X = ( 10 \times t ) / λ$$

t: Thickness (mm) of heat conduction sheet of Examples 1 to 4 or Comparative Example 1
λ: Thermal conductivity (W/(m·K))

### (Evaluation of Void Ratio at Interface)

In the three-layer structure sample prepared by the method described in (Measurement of thermal resistance), the void ratio at the interface was evaluated as follows. Using an ultrasonic image diagnostic device (Insight-300, Insight Co., Ltd.), the adhesion state at the interface was observed under the condition of a reflection method, 35 MHz, gain level of 10 dB, and contrast threshold of 30% to 70%. Furthermore, the image is binarized using image analysis software (ImageJ) (specifically, 0 to 83 of the histogram are black and 84 to 255 are white), the ratio of the area of the non-adhered gas region with respect to the area of Φ11 mm (area of the measurement region) was calculated, and the void ratio (%) at the interface was calculated based on the following formula.

$$Void ratio ( \% ) at interface = 100 \times ( area of gas region / area of measurement region )$$

### (Evaluation of Thickness)

Using a micrometer, the maximum thickness of the heat conduction sheet before compression (“Thickness before compression” in Table 2), the maximum thickness of the metal region before compression (“Thickness of metal region before compression” in Table 2), and the maximum thickness of the heat conduction sheet after compression (“Thickness after compression” in Table 2) were measured. Regarding the maximum thickness of the metal region before compression, the maximum thickness of the heat conduction layer before compression and the maximum thickness of the heat conduction sheet before compression were each obtained, and the maximum thickness of the metal region was obtained by subtracting the maximum thickness of the heat conduction layer before compression from the maximum thickness of the heat conduction sheet before compression.

TABLE 2

| | | Example | | | | |
|---|---|---|---|---|---|---|
| | | | | | | Comparative |
| | | Example 1 | Example 2 | Example 3 | Example 4 | Example 1 |
| Heat | K · | 0.114 | 0.089 | 0.101 | 0.097 | 0.115 |
| resistance | cm²/w | | | | | |
| Thickness | mm | 0.119 | 0.125 | 0.115 | 0.107 | 0.111 |
| before | | | | | | |
| compression | | | | | | |
| Thickness of | μm | 8 | 14 | — | — | — |
| metal region | | | | | | |
| before | | | | | | |
| compression | | | | | | |
| Thickness | mm | 0.102 | 0.095 | 0.101 | 0.094 | 0.092 |
| after | | | | | | |
| compression | | | | | | |
| Void ratio at | % | 1 | 0 | 3 | 1 | 9 |
| interface | | | | | | |

As shown in Examples 1 to 4 and Comparative Example 1, it was possible to reduce the thermal resistance of the heat conduction sheet by using the low melting point metal component.

Furthermore, it was possible to reduce the thermal resistance of the heat conduction sheet by decreasing the void ratio at the interface.

The entire contents of the disclosures by PCT/JP2022/028527 are incorporated herein by reference.

All publications, patent applications, and technical standards mentioned in the present specification are herein incorporated by reference to the same extent as if each individual publication, patent application, and technical standard were specifically and individually indicated to be incorporated by reference.

1. A heat conduction sheet, comprising:
a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet,
wherein the heat conduction sheet contains a metal component having a melting point of 200° C. or less.

2. The heat conduction sheet according to claim 1, wherein the metal component is particulate.

3. The heat conduction sheet according to claim 1, wherein the metal component is located on at least a part of a main surface of the heat conduction layer.

4. The heat conduction sheet according to claim 1, wherein the melting point of the metal component is 60° C. or more.

5. The heat conduction sheet according to claim 1, wherein the metal component contains at least one element selected from the group consisting of tin, bismuth, indium, zinc, lead, gallium, cadmium, thallium, and antimony.

6. The heat conduction sheet according to claim 1, wherein graphite particles (A): carbon fiber, which is a mass ratio of the graphite particles (A) and the carbon fiber in the heat conduction layer is from 100:0 to 100:30.

7. The heat conduction sheet according to claim 1, wherein the metal component is disposed on two main surfaces of the heat conduction layer.

8. The heat conduction sheet according to claim 1, wherein the metal component contains Sn—Bi solder, Sn—In solder, Bi—In solder, Sn—Zn solder, Bi—Sn—In solder, or Sn—Zn—Bi solder.

9. The heat conduction sheet according to claim 1, wherein a content ratio of the metal component contained in the heat conduction sheet is from 0.1% by volume to 20% by volume with respect to the total amount of the heat conduction sheet.

10. The heat conduction sheet according to claim 1, wherein the heat conduction layer contains a liquid component (B), and the liquid component (B) contains polybutene.

11. The heat conduction sheet according to claim 10, wherein a content ratio of the liquid component (B) is from 10% by volume to 55% by volume.

12. The heat conduction sheet according to claim 1, wherein the heat conduction layer contains an acrylic ester polymer (C).

13. The heat conduction sheet according to claim 1, wherein the heat conduction layer contains a hot melt agent (D).
